(19) United States
(12) Patent Application Publication
(10) Pub. No.: US 2011/0277828 A1
(43) Pub. Date: Nov. 17, 2011

(54) DISORDER-ORDER HOMOJUNCTIONS AS MINORITY-CARRIER BARRIERS

(75) Inventors: Mark W. Wanlass, Evergreen, CO (US); Angelo Mascarenhas, Golden, CO (US); Jeffrey J. Carapella, Golden, CO (US)

(73) Assignee: Alliance for Sustainable Energy, LLC, Golden, CO (US)

(21) Appl. No.: 13/146,643

(22) PCT Filed: Jan. 29, 2010
(86) PCT No.: PCT/US10/22629

§ 371 Date: Jul. 27, 2011

Related U.S. Application Data
(60) Provisional application No. 61/148,719, filed on Jan. 30, 2009.

(51) Int. Cl. H01L 31/06; H01L 31/0352

(52) U.S. Cl. 136/255; 438/93; 438/87; 257/E31.032

(57) ABSTRACT

A method for improving the overall quantum efficiency and output voltage in solar cells using spontaneous ordered semiconductor alloy absorbers to form a DOH below the front or above the back surface of the cell.

### PRIORITY CLAIM

This application claims priority to co-owned, co-pending U.S. Provisional Patent Application No. 61/148,719 entitled “Disorder-order homojunctions as minority-carrier barriers for improved device performance” filed on Jan. 30, 2009, which is hereby incorporated by reference as if fully set forth herein.

### CONTRACTUAL ORIGIN

The United States Government has rights in this invention under Contract No. DE-AC36-08G028308 between the United States Department of Energy and the Alliance for Sustainable Energy, LLC, the Manager and Operator of the National Renewable Energy Laboratory.

### TECHNICAL FIELD

The described subject matter relates to novel applications of disorder-order homojunctions (DOHs) as minority-carrier barriers for improved device performance, for example in solar cells.

### BACKGROUND

Devices are known which utilize Al-containing window layers, typically consisting of materials such as Al(Ga)In(As)P. The Al is highly reactive with trace amounts of O₂ and H₂O in the epitaxial crystal growth system, resulting in defects in the crystalline epilayers that degrade their electronic and photovoltaic quality. The degraded qualities result in problems such as high electrical resistance and ineffectual surface passivation and minority carrier confinement.

The quality of Al-containing epilayers can vary considerably depending on many factors such as precursor purity, relative atmospheric humidity, substrate loading procedures, etc. This variability is highly undesirable from the viewpoint of mass production of tandem solar cells.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods that are meant to be exemplary and illustrative, not limiting in scope. In various embodiments, one or more of the above-described problems have been reduced or eliminated, while other embodiments are directed to other improvements.

GaInP lattice matched (LM) to GaAs or Ge has been the high-band-gap material of choice for use in monolithic tandem solar cells such as GaInP/Ga(In)As/Ge or GaInP/GaAs/GaInAs. Lattice-mismatched (LMM) designs using lower band gaps, such as GaInP (1.7 eV)/GaInAs (1.2 eV)/Ge have also been successful. Recently, LMM high-band-gap GaInP cells (˜2.1 eV) have also been in development for eventual use in monolithic tandem solar cell designs. Thus, GaInP has broad applications in tandem solar cells with top subcell bandgaps ranging from about 1.7 to 2.2 eV.

A method of consistently reducing the surface recombination velocity to a very low value can lead to performance improvements, such that the cells are better than those made using conventional window layers. In other words, the blue response and output voltage may be better than achieved previously. Blue response is the photogenerated carrier collection efficiency of a solar cell for photon energies near the high-energy limit of the solar spectrum. Exemplary embodiments described herein include methods for improving the blue response and the output voltage in cells using GaInP absorbers without the use of conventional Al-containing window layers, and the resulting products and devices. Exemplary embodiments also include methods for forming minority-carrier barriers at the back surface of a solar cell (i.e., at the back of the base layer). Such barriers are useful in improving the red response and the output voltage. Red response is the photogenerated carrier collection efficiency of a solar cell for photon energies near its band gap. These methods may be implemented, e.g., in new high-band-gap GaInP alloys.

Exemplary embodiments described herein further include methods for improving the overall quantum efficiency and output voltage in solar cells is disclosed using spontaneous ordered semiconductor alloy absorbers to form a DOH below the front surface of the cell. These methods disclose a p-on-n doping architecture with respect to the front surface of the cell. In the exemplary method the depth of the DOH is 50-500 Angstroms and the overall quantum efficiency includes the blue response of the solar cell. However, other suitable depths may be apparent to those of ordinary skill in the art. In the exemplary method the overall quantum efficiency may be improved by including an additional lightly doped (5E17 cm̂-3, or lower) p-type layer below the DOH which will facilitate the placement the p/n junction deeper in the solar cell. Further, the exemplary method teaches that a larger fraction of absorbable photons within the solar cell are absorbed within the lightly doped p-type layer between said DOH and the p/n junction where the photo-generated electrons are efficiently collected. In the preferred method the thickness of the lightly doped p-type layer is 0 to 5 microns and the thickness of the n-type layer in the p/n junction is 100 Angstroms to 5 microns. However, other applicable thicknesses will be apparent for the p-type layer and the p/n junction to those of ordinary skill in the art.

In the exemplary method one of several approaches may be used to form the DOH: namely, adjusting crystal growth parameters, heavy doping with extrinsic impurities, growth using surfactants or other techniques apparent to those of ordinary skill in the art.

Another aspect of the exemplary method that promotes improved overall quantum efficiency and output voltage in solar cells is disclosed using spontaneous ordered semiconductor alloy absorbers to form a DOH above the back surface of the solar cell, when the solar cell is LMM to the substrate. In this exemplary case the doping architecture of the solar cell is n⁺/n/p/p⁺ and the solar cell comprises an n-on-p doping architecture with respect to the front surface of the cell and most preferably the thickness of the n⁺ layer is 50-500 Angstroms, the thickness of the n layer is 100 Angstroms to 5 microns, and the thickness of the p layer is 100 Angstroms to 5 microns. The DOH is formed at the p/p⁺ interface and the minimum thickness of the disordered layer of the DOH is 50-500 Angstroms. Given this characterization, the overall quantum efficiency includes the red response of the solar cell. Further to this characterization one or more of the following approaches is used to form the DOH: namely, adjusting crystal growth parameters, heavy doping with extrinsic impurities, or growth using surfactants. For the sake of clarity the heavy Zn doping is used to form the disordered layer of the DOH and the heavy Zn doping in the p⁺ layer forms a DOH at the p/p⁺ interface. As such the DOH may also form a minority-carrier barrier and a spontaneously ordered compound semiconductor alloy may be used to form the DOH.

Another exemplary optoelectronic device has minority-carrier barriers in the DOHs for front- and/or back-surface electron confinement. The exemplary device may be fabricated from spontaneously ordering compound semiconductor alloys. For optimum performance the DOH is defined as the interface between an epitaxial layer of GaₓIn₁₋ₓP with η˜0 and an epitaxial layer of GaₓIn₁₋ₓP with the same stoichiometric index x and with η>0. Further, the band gaps on adjacent sides of the DOH are different, the band-offset is in the conduction band, the interface of two epitaxial layers of GaₓIn₁₋ₓP and have the same value of x and η_{A}≠η_{B}. In this exemplary device the band offset of the larger band gap layer serves as a barrier to minority-carrier photogenerated electrons. Finally, the semiconductor alloy may consist of GaₓIn₁₋ₓP, AlₓIn₁₋ₓP, GaₓAs₁₋ₓP, GaₓAs₁₋ₓSb, InₓGa₁₋ₓAs or (Al₁₋ₓGaₓ)_{y}In_{1-y}P. However, other applicable alloys will be apparent to those of ordinary skill in the art.

In addition to the exemplary aspects and embodiments described above, further aspects and embodiments will become apparent by reference to the drawings and by study of the following descriptions.

### BRIEF DESCRIPTION OF THE DRAWINGS

Exemplary embodiments are illustrated in referenced figures of the drawings. It is intended that the embodiments and figures disclosed herein are to be considered illustrative rather than limiting.

FIG. 1 shows exemplary spectral quantum efficiency data for two different p⁺/p/n high-band-gap GaInP solar cells employing front-surface DOHs formed by doping heavily with Zn.

FIG. 2 shows exemplary spectral internal quantum efficiencies for two 2.1-eV n-on-p shallow-homojunction GaInP solar cells grown lattice mismatched on GaAs substrates using GaAsP compositionally step-graded layers.

FIGS. 3a-b show (a) exemplary spectral internal quantum efficiency data, and (b) current density (voltage) data; both for 2-eV, LMM GaInP solar cells grown on GaAs substrates using GaAsP compositionally step-graded layers.

FIG. 4 is an exemplary room temperature photoluminescence (PL) spectra for laser and detection polarizations oriented along the two cleavage directions.

### DETAILED DESCRIPTION

Briefly, novel applications of disorder-order homojunctions (DOHs) as minority-carrier barriers for improved device performance, and for example in high-band-gap (e.g., in the range of about 1.7 to about 2.1 eV) GaInP solar cells, are disclosed. LM GaInP alloys can be made to order spontaneously on the group-III sublattice under appropriate growth conditions. A disordered alloy can also be achieved by choosing the appropriate growth conditions. The band gap of the alloy depends on the degree of ordering, which is quantified by the ordering parameter. A fully disordered alloy has an ordering parameter equal to zero; a fully ordered alloy has an ordering parameter of unity. The band gap is minimized (to about 1.8 eV) when the alloy is fully ordered and maximized (to about 1.9 eV) when the alloy is fully disordered. Other mechanisms are available to disorder an otherwise ordered alloy. For example, surfactants (e.g., Sb and Te) and other impurities used for extrinsic doping (e.g., S and Zn) can disorder the alloy. A DOH is formed at the interface between a substantially disordered alloy and a substantially ordered alloy.

As described in more detail below, a DOH can be used to confine minority electrons in partially ordered p-GaInP. Exemplary embodiments may be used for developing efficient high-band-gap GaInP solar cells. Indeed, new applications may also be important for a wide range of III-V-alloy based devices, including other solar cells and more generally to other minority-carrier devices.

Exemplary novel applications of DOHs as minority-carrier barriers for improved device performance, and for example in high-band-gap (in the range of about 1.7 to about 2.1 eV) GaInP solar cells, may be better understood with reference to the Figures and following discussion.

DOHs may be used in applications such as, e.g., aluminum-free minority-carrier barriers for III-V compound semiconductor solar photovoltaic devices. Spontaneous CuPt atomic ordering occurs in all zinc-blende ternary, quaternary, etc. III-V semiconductor alloys comprised of Al, Ga, In, As, P, and Sb when grown by metalorganic chemical vapor deposition (MOCVD) on (001) substrates, and the extent or degree of ordering (described by a statistical order parameter 0≧η≧1) is determined by numerous growth parameters (growth temperature, growth rate, partial pressure, substrate misorientation, doping, and surfactant effects, etc.). The ordering phenomenon is driven by processes occurring at the epitaxial growth surface (steps, reconstruction, dimerization, etc.) and it is suspected that hydrogen (present in MOCVD reactors) plays a role in stabilizing this. In samples grown on (001) substrates tilted by a few degrees (about 2°) towards [011] only single variant ordering is observed. A unique electronic feature of spontaneous ordering is the lowering of the band gap as η increases from 0 to 1, whilst concomitantly maintaining a fixed lattice constant. Another key feature of spontaneous ordering is that the lowering of the band gap occurs mainly by a lowering of the conduction band at gamma (Γ) whereas the valence band remains relatively fixed. It has also been established that η evolves from very low values at the first initiation of epitaxial growth to larger values as the film thickness evolves.

Although most past studies of spontaneous ordering in GaₓIn₁₋ₓP have been for values of x=0.5, at which this alloy is lattice matched to GaAs substrates, we have recently observed strong ordering induced band gap reductions in alloys of GaₓIn₁₋ₓP for values of x>0.5 (x is in the range of about 0.7 to about 0.75).

The interface between an epitaxial layer of GaₓIn₁₋ₓP with η=0 and an epitaxial layer of GaₓIn₁₋ₓP with the same stoichiometric index x but with η>0 constitutes a DOH. Not only are the band gaps on adjacent sides of the junction different, but the band line-up is such that almost all the band-offset is in the conduction band. A similar situation arises at the interface of two epitaxial layers A and B of GaₓIn₁₋ₓP that have the same value of x but for which η_{A}≠η_{B}. The conduction band offset of the larger band gap layer (i.e., layer with smaller η) may serve as an effective potential barrier to minority-carrier photogenerated electrons.

Zn doping can significantly lower the value of η in partially ordered GaₓIn₁₋ₓP. For a solar PV device with a p-emitter/n-base doping architecture, where the emitter and base are grown epitaxially using GaₓIn₁₋ₓP with η>0 and with Zn as the p-dopant, and the introduction of a very heavy Zn doping spike for a GaₓIn₁₋ₓP overlayer with the same value of x as the emitter, induces the formation of a very thin (50-500 Å) disordered GaₓIn₁₋ₓP surface epilayer with a value of η about 0. The higher band gap and the conduction band offset of this epilayer with respect to the emitter provides very efficient minority carrier confinement while concomitantly facilitating majority carrier transport and being substantially optically transparent.

This is also applicable to GaₓIn₁₋ₓP emitter/base layers that have x greater than about 0.52. The thin disordered top epilayer provides a method for naturally obtaining an aluminum-free window layer for GaₓIn₁₋ₓP cells grown lattice matched or lattice mismatched to GaAs or Ge substrates, thus surmounting a long-standing difficulty that has plagued the field of photovoltaic devices.

Although heavy Zn doping may be utilized to cause the disordering of GaₓIn₁₋ₓP, it is understood that all semiconductor ternary, quaternary, etc. alloys that exhibit spontaneous ordering, as well as all methods that control the degree of order η, may be implemented. For other examples, see, e.g., “Spontaneous Ordering In Semi-Conductor Alloys,” published by Springer and edited by Angelo Mascarenhas, Apr. 30, 2002, hereby incorporated by reference for all that it discloses.

In an exemplary embodiment, p-on-n GaInP solar cells with excellent blue response can be developed by forming a DOH right near the surface (e.g., about 250 Å deep, although the depth can be varied) through the use of heavy Zn doping. The high response can be extended to longer wavelengths by including a more lightly doped p-region below the DOH to place the p/n junction deeper in the structure. With this design, a larger fraction of the absorbable photons get absorbed between the DOH and the p/n junction, where the electrons are collected very efficiently. Thus, the Zn-doping-induced DOH works well with the p/n doping architecture for the cell. An n-region is included below the p-region to define the position of the p/n junction. Thus, the overall doping architecture becomes p⁺/p/n.

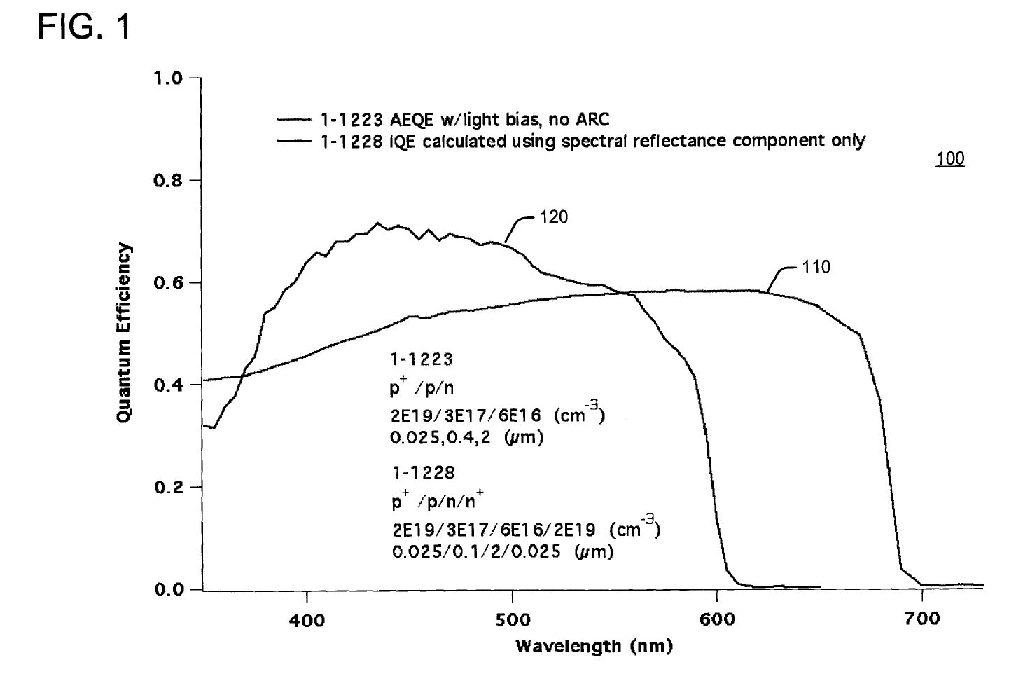

FIG. 1 shows exemplary spectral quantum efficiency data 100 for p⁺/p/n high-band-gap GaInP solar cells employing front-surface DOHs formed by doping heavily with Zn. The curve 110 shows absolute external quantum efficiency data for a GaInP cell lattice matched to GaAs (band gap ˜1.8 eV). The cell has grid coverage of about 11%, and it does not have an anti-reflection coating. The curve 120 shows internal quantum efficiency data for a lattice-mismatched GaInP cell (having a band gap of about 2.1 eV) grown on GaAs. The true internal quantum efficiency of this device is actually higher because only the specular component of the reflectance was used to calculate the data.

The data for the lattice-matched GaInP cell is outstanding, particularly at 350 nm, where the internal quantum efficiency is over approximately 80% (considering grid coverage and approximate reflectance). The surface recombination velocity for this cell is approaching zero. The one-sun efficiencies for these cells without an anti-reflection coating, and with high (about 11%) grid coverage is about 11.1%.

The best quantum efficiencies are observed for lattice-matched GaInP cells. But the higher-band-gap lattice-mismatched cell also shows excellent blue response, also indicating a low surface recombination velocity. Spontaneous ordering was observed in both the lattice-matched GaInP and the higher-band-gap, lattice mismatched GaInP. Accordingly, the Zn-doping-induced DOH is successful in both of these new cell structures.

It is noted that p-on-n cells have a high emitter sheet resistance due to the relatively lower mobility of majority-carrier holes in p-type material as compared to electrons in n-type material. Thus, the emitter sheet resistance of such devices may be on the order of 10⁴ ohms per square, or more. Accordingly, these techniques may be particularly suitable for use in space-power tandem-cell applications.

The Zn-doping-induced DOH may also be applied for back-surface electron confinement in n-on-p higher-band-gap (in the range of about 1.9 to about 2.2 eV) GaInP solar cells grown lattice mismatched on GaAs substrates. The doping architecture for these cells is n⁺/n/p/p⁺. The heavy Zn doping in the p⁺ layer forms the DOH at the p/p⁺ interface.

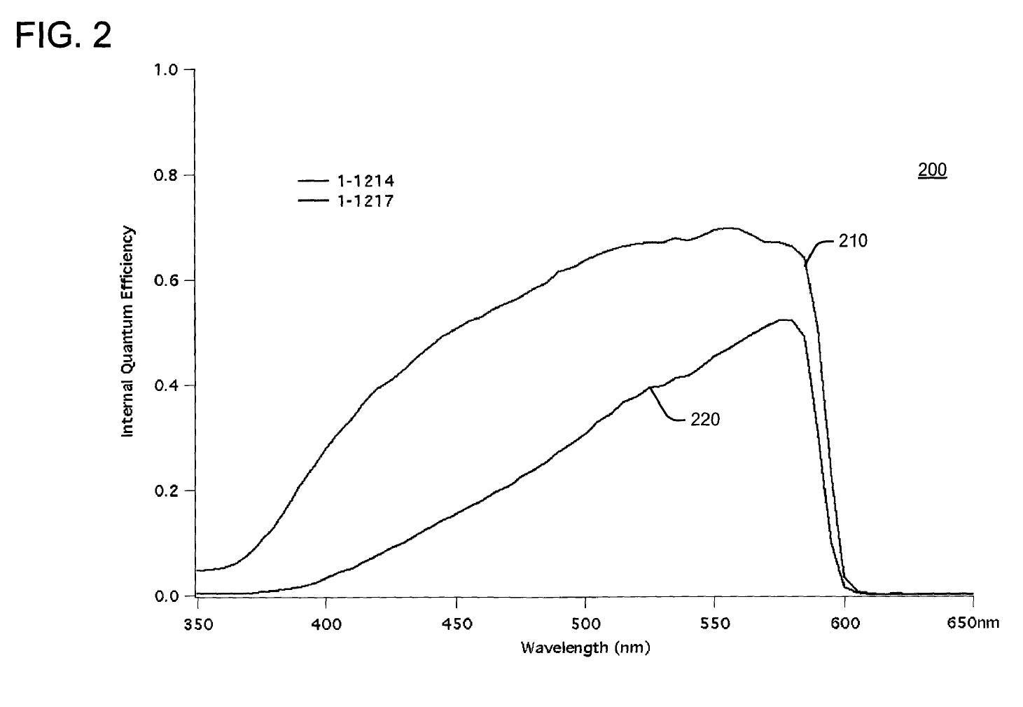

FIG. 2 shows exemplary spectral internal quantum efficiencies 200 for two 2.1-eV n-on-p shallow-homojunction GaInP solar cells grown lattice mismatched on GaAs substrates using GaAsP compositionally step-graded layers. Improvement in the internal quantum efficiency can be seen when a DOH is included at the back of the base layer in an 2.1-eV n-on-p shallow-homojunction GaInP solar cell.

Data 210 for the cell with the DOH at the back surface of the p-base layer exhibits a substantially higher performance as compared to data 220 for the cell without the DOH. The DOH strongly reduces the number of minority electrons that diffuse out of the back of the p-base layer into the GaAsP graded region, where they are lost due to recombination. The true internal quantum efficiencies of these devices are actually higher because only the specular component of their reflectance was used to calculate the data. Non-planar surface morphologies are typical for these lattice-mismatched cells, which result in a fraction of the reflectance being diffuse.

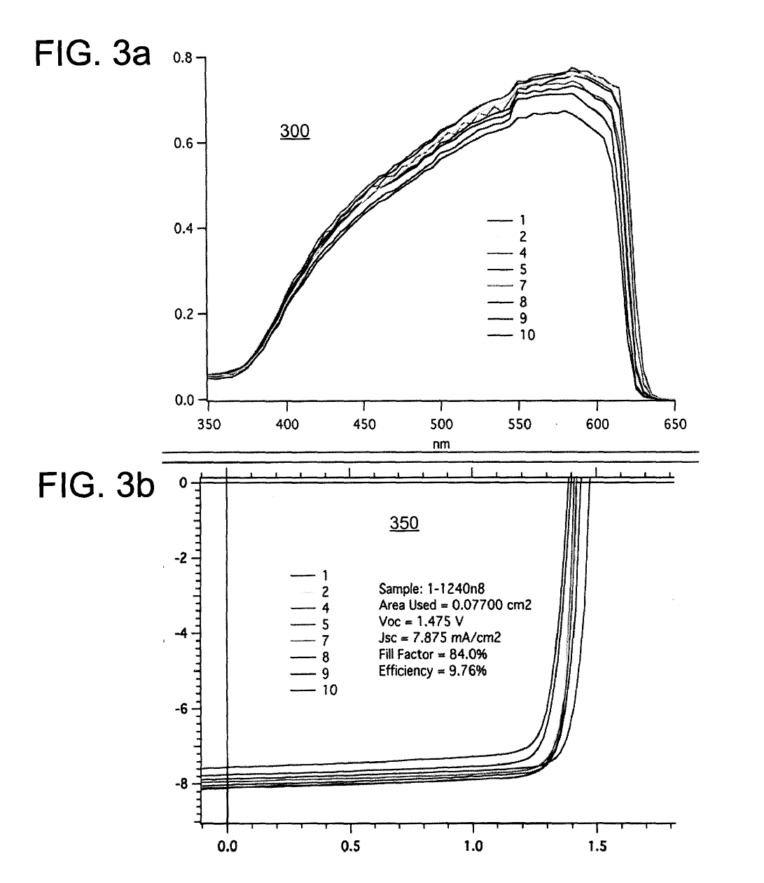

FIGS. 3a-b show (a) exemplary spectral internal quantum efficiency data 300, and (b) current density (voltage) data 350; both for ten 2-eV, LMM n/p GaInP solar cell samples grown on GaAs substrates using GaAsP compositionally step-graded layers. The same back-surface DOH confinement technique was applied to 2-eV GaInP cells and even better results were observed. The cells exhibit high efficiency, considering the 2-eV band gap. The internal quantum efficiency data was calculated using only the specular component of the reflectance. Accordingly, the actual values are somewhat higher. The current (voltage) data was measured using the XT-10 solar simulator for one-sun, global conditions at 25° C. A calibrated 2.1-eV GaInP cell was used to set the correct intensity. The data for the cells shown in FIGS. 3a-b were based on a cell that did not have an anti-reflection coating (ARC) applied. It is noted that using an ARC, the efficiency of the best cell is about 15%. These results illustrate that the back-surface DOH confinement technique provides a substantial performance boost when applied to high-band-gap, LMM, n/p GaInP solar cells.

### EXAMPLE

Characterization of the materials confirms that DOHs are formed in the high-band-gap GaInP alloys. In this example, the following measurement was used to demonstrate the existence of spontaneous ordering in GaₓIn₁₋ₓP (where x>0.5). The epilayers were grown on GaAs substrates with surface normal tilted 2° from toward [110]. Room temperature photoluminescence (PL) was excited with a 532 nm laser at 200 W/cm². A polarized laser was equipped with a waveplate in order to rotate the laser polarization to either of two orthogonal directions in the plane of the sample: [symbol] or [⁻]. The PL was detected through a broadband waveplate and polarizer, which enabled the PL component in both of these directions to be independently recorded.

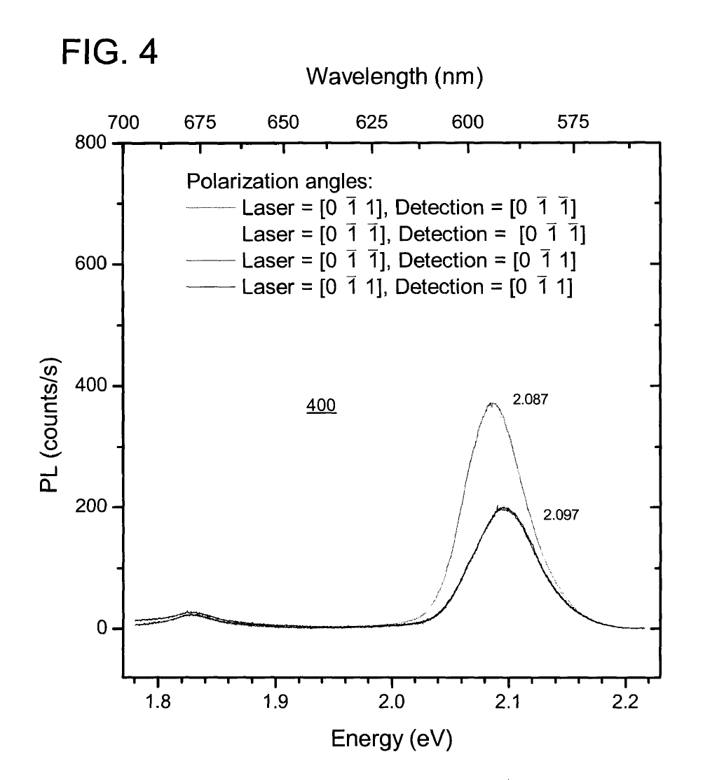

FIG. 4 is an exemplary room temperature photoluminescence (PL) spectra 400 for laser and detection polarizations oriented along the two cleavage directions. Results are shown for a 72% gallium sample. The four PL spectra correspond to the two excitation polarizations and two detection polarizations. Approximate peak energy is 2.10 eV (electron volts), which is 90 meV (milli electron volts) below the band gap of disordered Ga_{0.72}In_{0.28}P. Comparing with a lattice matched composition, x=0.52, the band gap reduction shown in FIG. 4 corresponds to a relatively strong ordering.

Another important result is the anisotropy in the data. FIG. 4 shows that PL is stronger and peaks at a lower energy when emitted parallel to [symbol] . However, rotating the laser polarization for each component had no effect.

The laser independence was expected because the photon energy is far above the band gap, and because photogenerated carriers lose momentum orientation during the energy relaxation that precedes recombination. The emission anisotropy is a direct result of spontaneous ordering, which causes a heavy-hole-light-hole valence band splitting (VBS). Just as in uniaxial strain, or crystal field splitting, the heavy-hole transition is disallowed for an electric field polarized along the uniaxis. The two possible ordering directions for [100] GaInP are [⁻] and [⁻], both of which have in-plane projections along or opposite to [⁻]. PL polarized along this projection has the heavy hole (HH) partially absent. Combining this selection rule with the intrinsically smaller light hole (LH) matrix element, and the relatively small VBS compared to kT, results in PL spectra that include a single peak dominated by the lower energy HH along [symbol] and by the higher energy LH along [⁻]. This is observed in FIG. 4, thereby confirming the presence of ordering in the sample.

Similar characterization of GaInP grown lattice matched to GaAs from the MOVPE crystal growth system was also performed. The GaInP is strongly ordered, suggesting that the Zn-doping-induced DOH is easy to implement at the surface of such layers. For the conditions used in this growth process, GaInP alloys with band gaps ranging from about 1.8 to about 2.1 eV are significantly ordered.

It is noted that the example discussed above is provided for purposes of illustration and is not intended to be limiting. Still other embodiments and modifications are also contemplated.

While a number of exemplary aspects and embodiments have been discussed above, those of skill in the art will recognize certain modifications, permutations, additions and sub combinations thereof. It is therefore intended that the following appended claims and claims hereafter introduced are interpreted to include all such modifications, permutations, additions and sub-combinations as are within their true spirit and scope.

1. A method for improving the overall quantum efficiency and output voltage in solar cells using spontaneous ordered semiconductor alloy absorbers to form a DOH below the front surface of the cell.

2. The method of claim 1, wherein the solar cell comprises a p-on-n doping architecture with respect to the front surface of the cell.

3. The method of claim 1, wherein the depth of the DOH is 50-500 Angstroms.

4. The method of claim 1, wherein the overall quantum efficiency includes the blue response of the solar cell.

5. The method of claim 1, wherein the overall quantum efficiency is improved by including an additional lightly doped p-type layer below the DOH thus placing the p/n junction deeper in the solar cell.

6. The method of claim 1, wherein a larger fraction of absorbable photons within the solar cell are absorbed within the lightly doped p-type layer between said DOH and the p/n junction where the photo-generated electrons are efficiently collected.

7. The method of claim 6, wherein the thickness of the lightly doped p-type layer is 0 to 5 microns.

8. The method of claim 6, wherein the thickness of the n-type layer in the p/n junction is 100 Angstroms to 5 microns.

9. The method of claim 1, wherein at least one of the following approaches is used to form the DOH: adjusting crystal growth parameters, heavy doping with extrinsic impurities, or growth using surfactants.

10. The method of claim 9, wherein heavy Zn doping is used to form the DOH, which is consistent with a p-on-n doping architecture for the solar cell.

11. A method for improving the overall quantum efficiency and output voltage in solar cells using spontaneous ordered semiconductor alloy absorbers to form a DOH above the back surface of the solar cell, when the solar cell is LMM to the substrate.

12. The method of claim 11, wherein the doping architecture of the solar cell is n⁺/n/p/p⁺.

13. The method of claim 11, wherein the solar cell comprises an n-on-p doping architecture with respect to the front surface of the cell.

14. The method of claim 12, wherein the thickness of the n⁺ layer is 50-500 Angstroms, the thickness of the n layer is 100 Angstroms to 5 microns, and the thickness of the p layer is 100 Angstroms to 5 microns.

15. The method of claim 11, wherein the DOH is formed at the p/p⁺ interface.

16. The method of claim 11, wherein the minimum thickness of the disordered layer of the DOH is 50-500 Angstroms.

17. The method of claim 11, wherein the overall quantum efficiency includes the red response of the solar cell.

18. The method of claim 11, wherein at least one of the following approaches is used to form the DOH: adjusting crystal growth parameters, heavy doping with extrinsic impurities, or growth using surfactants.

19. The method of claim 18, wherein heavy Zn doping is used to form the disordered layer of the DOH.

20. The method of claim 18, wherein heavy Zn doping in the p⁺ layer forms a DOH at the p/p⁺ interface.

21. The method of claim 11, wherein the DOH forms a minority-carrier barrier.

22. The method of claim 11, wherein a spontaneously ordered compound semiconductor alloy is used to form the DOH.

23. An optoelectronic device having minority-carrier barriers comprising DOHs for front- and/or back-surface electron confinement.

24. The optoelectronic device of claim 23 fabricated from spontaneously ordering compound semiconductor alloys.

25. The optoelectronic device of claim 23 for use in high-band-gap GaInP alloys.

26. The optoelectronic device of claim 23, wherein the DOH is defined as the interface between an epitaxial layer of GaₓIn₁₋ₓP with η˜0 and an epitaxial layer of GaₓIn₁₋ₓP with the same stoichiometric index x and with η>0.

27. The optoelectronic device of claim 23, wherein the band gaps on adjacent sides of the DOH are different and the band-offset is in the conduction band.

28. The optoelectronic device of claim 23, wherein the interface of two epitaxial layers of GaₓIn₁₋ₓP have the same value of x and η_{A}≠η_{B}.

29. The optoelectronic device of claim 23, wherein the conduction band offset of the larger band gap layer serves as a barrier to minority-carrier photogenerated electrons.

30. The methods of claim 1 or 11, wherein the semiconductor alloy is GaₓIn₁₋ₓP, AlₓIn₁₋ₓP, GaₓAs₁₋ₓP, GaₓAs₁₋ₓSb, InₓGa₁₋ₓAs or (Al₁₋ₓGaₓ)_{y}In_{1-y}P.
